(19) United States
(12) Patent Application Publication
(10) Pub. No.: US 2026/0173697 A1
(43) Pub. Date: Jun. 18, 2026

(54) DISPLAY PANEL AND DISPLAY DEVICE

(71) Applicants: Hefei Visionox Technology Co., Ltd., Hefei (CN); Hefei Visionox Electronics Co., Ltd., Hefei (CN); VISIONOX TECHNOLOGY INC., Jiangsu (CN)

(72) Inventors: Zhiwei ZHOU, Hefei (CN); Jinfang ZHANG, Hefei (CN); Yulong MA, Hefei (CN); Tian WANG, Hefei (CN); Chung-Chun LEE, Hefei (CN)

(73) Assignees: Hefei Visionox Technology Co., Ltd., Hefei (CN); Hefei Visionox Electronics Co., Ltd., Hefei (CN); VISIONOX TECHNOLOGY INC., Jiangsu (CN)

(21) Appl. No.: 19/260,746

(22) Filed: Jul. 7, 2025

(30) Foreign Application Priority Data
Dec. 13, 2024 (CN) 202411847065.X

(51) Int. Cl. H10K 59/35; G06F 3/044; H10K 59/122; H10K 59/123; H10K 59/124; H10K 59/131; H10K 59/40; H10K 59/80

(52) U.S. Cl. CPC H10K 59/353; G06F 3/0446; H10K 59/122; H10K 59/123; H10K 59/124; H10K 59/131; H10K 59/352; H10K 59/40; H10K 59/8792

(57) ABSTRACT

A display panel and a display device. The display panel includes a substrate, a first insulating layer, a first electrode layer, and a touch electrode layer. The substrate is provided with a thin-film transistor on one side of the substrate. The first insulating layer is disposed on the side of the thin-film transistor facing away from the substrate and provided with a connecting via penetrating the first insulating layer. The first electrode layer includes a first electrode electrically connected to the thin-film transistor through the connecting via. The touch electrode layer includes a touch electrode. The touch electrode is located on the side of the first electrode layer facing away from the substrate. The touch electrode includes a touch line. The orthographic projection of the touch line on the substrate at least partially overlaps the orthographic projection of the connecting via on the substrate.

### CROSS-REFERENCE TO RELATED APPLICATION(S)

This application claims priority of a Chinese Patent Application filed with China National Intellectual Property Administration (CNIPA) on Dec. 13, 2024, with application No. 202411847065.X, the disclosure of which is incorporated herein by reference in its entirety.

### TECHNICAL FIELD

This application relates to the field of display, particularly a display panel and a display device.

### BACKGROUND

Flat panel display devices based on organic light-emitting diode (OLED) and light-emitting diode (LED) technologies are widely used in various consumer electronics such as mobile phones, televisions, laptops, and desktop computers due to the advantages of flat panel display devices, including high image quality, low power consumption, thin body, and broad application range, making flat panel display devices the mainstream in the display technology.

However, the use performance of current OLED display products remains to be improved.

### SUMMARY

Embodiments of this application provide a display panel and a display device to improve the use performance of OLED display products.

An embodiment of a first aspect of this application provides a display panel. The display panel includes a substrate, a first insulating layer, a first electrode layer, and a touch electrode layer. The substrate is provided with a thin-film transistor on one side of the substrate. The first insulating layer is disposed on a side of the thin-film transistor facing away from the substrate and is provided with a connecting via penetrating the first insulating layer. The touch electrode layer includes a touch electrode located on a side of the first electrode layer facing away from the substrate. The touch electrode includes a touch line. An orthographic projection of the touch line on the substrate at least partially overlaps an orthographic projection of the connecting via on the substrate.

An embodiment of the first aspect of this application provides a display panel. The display panel includes a substrate, a first electrode layer, an isolation structure, and a touch electrode layer. The first electrode layer is disposed on a side of the substrate and includes a first electrode. The isolation structure is located on the side of the substrate, an isolation opening is formed by being enclosed by the isolation structure, an orthographic projection of the first electrode on the substrate at least partially overlaps an orthographic projection of the isolation opening on the substrate, and the isolation structure includes a body portion and a recessed portion recessed from the body portion toward the substrate. The touch electrode layer is located on a side of the isolation structure facing away from the substrate and includes a touch line, and an orthographic projection of the recessed portion on the substrate at least partially overlaps an orthographic projection of the touch line on the substrate.

An embodiment of the first aspect of this application provides a display panel. The display panel includes a substrate, a first electrode layer, an isolation structure, and a light-shielding layer. The first electrode layer is disposed on one side of the substrate and includes a first electrode. The isolation structure is located on one side of the substrate. An isolation opening is formed by being enclosed by the isolation structure. The orthographic projection of the first electrode on the substrate at least partially overlaps the orthographic projection of the isolation opening on the substrate. The isolation structure includes a body portion and a recessed portion recessed from the body portion toward the substrate. The light-shielding layer is located on the side of the isolation structure facing away from the substrate. The light-shielding layer includes a light-shielding portion. The orthographic projection of the recessed portion on the substrate at least partially overlaps the orthographic projection of the light-shielding portion on the substrate.

An embodiment of a second aspect of this application provides a display device. The display device includes the display panel of any previous embodiment.

The display panel of any embodiment of this application includes a substrate, a first insulating layer, a first electrode layer, and a touch electrode layer. The first insulating layer is provided with a connecting via so that the first electrode can be electrically connected to the thin-film transistor through the connecting via, and the thin-film transistor can transmit signals to the first electrode. The touch electrode layer includes a touch electrode. The touch electrode includes a touch line. The touch line is configured to transmit touch signals to implement a touch function of the display panel. Since the first insulating layer is provided with the connecting via, the film layer on the side of the first insulating layer facing away from the substrate may be recessed in the region where the connecting via is located, resulting in an uneven surface of the film layer. The connecting via is filled with metal material including the first electrode. The metal material reflects light. The light reflected by the uneven surface may affect the display effect of the display panel. In embodiments of this application, the orthographic projection of the touch line on the substrate at least partially overlaps the orthographic projection of the connecting via on the substrate, and the touch line covers part of the connecting via to cover part of the uneven surface, improving the display effect of the display panel and the use performance of the display panel.

### BRIEF DESCRIPTION OF DRAWINGS

Other features, objects, and advantages of this application are clearer from the following detailed description of non-limiting embodiments with reference to drawings. The same or similar reference numerals indicate the same or similar features. The drawings are not drawn to the actual scale.

FIG. 1 is a diagram illustrating the structure of a display panel according to an embodiment of this application.

FIG. 2 is a section view taken along A-A of FIG. 1.

FIG. 3 is a diagram illustrating the structure of a display panel according to an embodiment of this application.

FIG. 4 is a diagram illustrating the structure of a display panel according to an embodiment of this application.

FIG. 5 is a section view taken along B-B of FIG. 4.

FIG. 6 is a section view taken along C-C of FIG. 4.

FIG. 7 is a diagram illustrating the structure of a display panel according to an embodiment of this application.

FIG. 8 is a diagram illustrating the structure of a display panel according to an embodiment of this application.

FIG. 9 is a diagram illustrating the structure of a display panel according to an embodiment of this application.

### REFERENCE LIST

110. substrate; 120. thin-film transistor; 130. first insulating layer; 131. connecting via; 131a. first via; 131b. second via; 131c. third via;
200. isolation structure; 201. first sublayer; 202. second sublayer; 210. isolation opening; 220. body portion; 230. recessed portion; 270. light-shielding layer;
300. pixel definition layer; 310. light-emitting unit; 311. first light-emitting unit; 312. second light-emitting unit; 313. third light-emitting unit; 320. pixel defining portion; 330. pixel opening; 331. first-type pixel opening; 332. second-type pixel opening; 333. third-type pixel opening; 330a. first pixel opening; 330b. second pixel opening; 330c. third pixel opening;
400. encapsulation layer; 401. first encapsulation layer; 402. second encapsulation layer; 403. third encapsulation layer; 410. encapsulation portion;
500. touch electrode layer; 501. first touch electrode; 501 a. first touch portion; 501 b. first connecting portion; 502. second touch electrode; 502a. second touch portion; 502b. second connecting portion; 503. dummy electrode; 510. touch electrode; 510a. touch line; 511. first line; 511a. first side edge; 511b. second side edge; 512. second line; 513. third line; 514. fourth line; 515. fifth line; 516. sixth line; 520. first touch layer; 521. first touch segment; 530. second touch layer; 531. second touch segment; 540. an insulating dielectric layer; 541. dielectric via; 560. notch;
600. first electrode layer; 610. first electrode;
700. second electrode;
Q1. first gap; Q2. second gap; Q3. third gap; Q4. fourth gap; Y. first direction; X. second direction

### DETAILED DESCRIPTION

Features and example embodiments in various aspects of this application are described hereinafter in detail. To provide a clearer understanding of the objects, technical solutions, and advantages of this application, this application is further described below in detail in conjunction with drawings and embodiments. It is to be understood that the embodiments described here are only configured to illustrate and not to limit this application. For those skilled in the art, this application may be implemented without some of these details. The following description of the embodiments is intended to provide a better understanding of this application through examples of this application.

It is to be understood that when the structure of a component is described and a layer or region is referred to as “on” or “above” another layer or region, the layer or region is directly located on another layer or region, or other layers or regions are included between the layer or region and another layer or region. If the component is turned over, the layer or region is located “below” or “underneath” another layer or region.

Embodiments of this application provide a display panel and a display device. Various embodiments of the display panel and the display device are described hereinafter in conjunction with drawings.

An embodiment of this application provides a display panel. The display panel may be an OLED display panel.

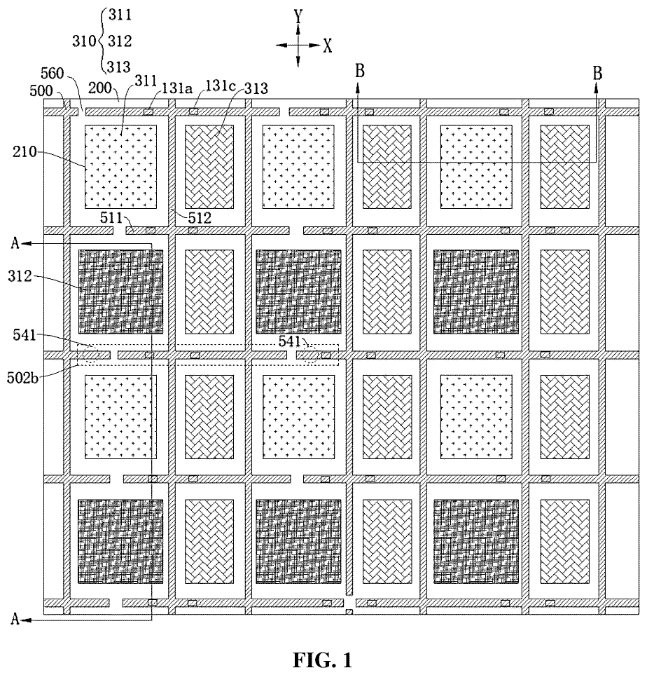

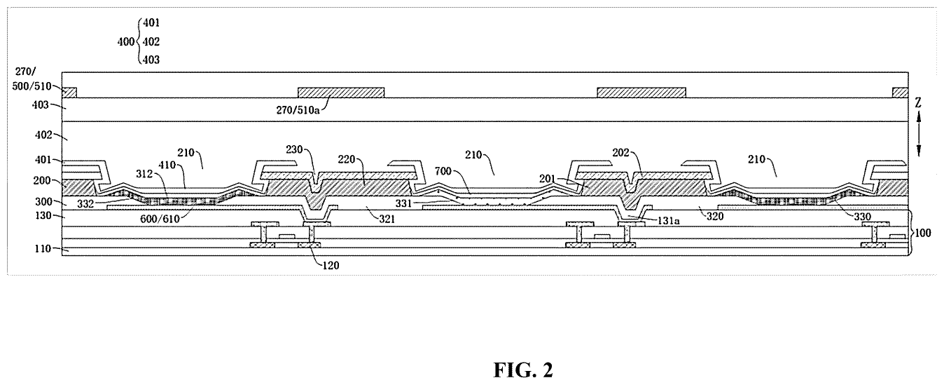

Referring to FIG. 1 to FIG. 3, FIG. 1 is a diagram illustrating the structure of a display panel according to an embodiment of this application. FIG. 2 is a section view taken along A-A of FIG. 1.

As shown in FIG. 1 and FIG. 2, an embodiment of a first aspect of this application provides a display panel. The display panel includes a substrate 110, a first insulating layer 130, a first electrode layer 600, and a touch electrode layer 500. The substrate 110 is provided with thin-film transistors 120 on one side of the substrate 110. The first insulating layer 130 is disposed on the side of the thin-film transistors 120 facing away from the substrate 110 and provided with connecting vias 131 penetrating the first insulating layer 130. The first electrode layer 600 includes first electrodes 610. The first electrodes 610 are electrically connected to the thin-film transistors 120 through the connecting vias 131. The touch electrode layer 500 includes touch electrodes 510. The touch electrodes 510 are located on the side of the first electrode layer 600 facing away from the substrate 110. The touch electrodes 510 include touch lines 510a. The orthographic projection of a touch line 510a on the substrate 110 at least partially overlaps the orthographic projection of a connecting via 131 on the substrate 110.

The display panel of this embodiment of this application includes a substrate 110, a first insulating layer 130, a first electrode layer 600, and a touch electrode layer 500. The first insulating layer 130 is provided with connecting vias 131 so that the first electrodes 610 can be electrically connected to the thin-film transistors 120 through the connecting vias 131, and the thin-film transistors 120 can transmit signals to the first electrodes 610. The touch electrode layer 500 includes touch electrodes 510. The touch electrodes 510 include touch lines 510a. Each touch electrode 510 includes multiple touch lines 510a intersecting with each other to form a grid. The touch electrodes 510 can sense an external input in a capacitive manner to implement a touch function of the display panel.

As shown in FIG. 2, since the first insulating layer 130 is provided with the connecting vias 131, the film layer located on the side of the first insulating layer 130 facing away from the substrate 110 may be recessed in the regions where the connecting vias 131 are located, resulting in an uneven surface of the film layer on the connecting vias 131. The uneven film layer reflects light. The light reflected by the uneven surface may affect the display effect of the display panel, for example, resulting in the problem of display uniformity in the screen-off state. In this embodiment of this application, the orthographic projection of the touch line 510a on the substrate 110 at least partially overlaps the orthographic projection of the connecting via 131 on the substrate 110, and the touch line 510a covers part of the connecting via 131 to cover part of the uneven surface, improving the display effect of the display panel and the use performance of the display panel.

In one or more embodiments, a driving circuit layer may be disposed on the substrate 110. In one or more embodiments, a first conductive layer, a second conductive layer, and a third conductive layer are stacked on one side of the substrate 110. An insulating layer is disposed between each two adjacent conductive layers. Illustratively, the driving circuit layer includes a pixel circuit. The pixel circuit includes a thin-film transistor 120 and a storage capacitor. The thin-film transistor 120 includes a semiconductor, a gate, a source, and a drain. The storage capacitor includes a first plate and a second plate. In an example, the gate and the first plate may be located in the first conductive layer, the second plate may be located in the second conductive layer, and the source and the drain may be located in the third conductive layer.

In one or more embodiments, the first insulating layer 130 may be a planarization layer to improve the flatness of the film layer on the side of the driving circuit layer.

In one or more embodiments, the first electrodes 610 are arranged in an array. Each first electrode 610 corresponds to a light-emitting unit 310 of the display panel.

In some embodiments, the orthographic projection of the connecting via 131 on the substrate 110 is located within the orthographic projection of the touch line 510a on the substrate 110 so that the touch line 510a can completely cover the connecting via 131. Since the connecting via 131 may cause the surface of other film layers to be uneven, the touch line 510a completely covers the uneven surface at the position corresponding to the connecting via 131 to avoid the emission difference caused by the uneven surface, thereby better improving the display effect of the display panel.

In one or more embodiments, the width of the touch line 510a may be slightly larger than the aperture of the connecting via 131 so that the touch line 510a can better cover the connecting via 131.

In some embodiments, the display panel also includes a pixel definition layer 300. The pixel definition layer 300 is disposed on the side of the first insulating layer 130 facing away from the substrate 110. The pixel definition layer 300 includes a pixel defining portion 320 and pixel openings 330. In one or more embodiments, the pixel openings 330 are arranged in an array.

In one or more embodiments, a light-emitting unit 310 may be disposed in a pixel opening 330, and a second electrode layer is disposed on the side of the pixel definition layer 300 and the light-emitting unit 310 facing away from the substrate 110. The second electrode layer may be a surface electrode, or the second electrode layer includes second electrodes 700 covering light-emitting units 310. One of the second electrodes 700 or the first electrodes 610 is a cathode. The other of the second electrodes 700 or the first electrodes 610 is an anode. This embodiment of this application uses an example in which the first electrodes 610 are the anode and the second electrodes 700 are the cathode.

In one or more embodiments, an encapsulation layer 400 is disposed on the side of the second electrode layer facing away from the substrate 110. The encapsulation layer 400 is configured to encapsulate the light-emitting units 310, alleviating the influence of water and oxygen intrusion on light emission of the light-emitting units 310. The touch electrode layer 500 may be located on the side of the encapsulation layer 400 facing away from the substrate 110 to alleviate the influence of the touch electrode layer 500 on the encapsulation effect of the encapsulation layer 400. In one or more embodiments, the encapsulation layer 400 includes a first encapsulation layer 401, a second encapsulation layer 402, and a third encapsulation layer 403. The first encapsulation layer 401 includes encapsulation portions 410 located on the side of the light-emitting units 310 facing away from the substrate 110.

In one or more embodiments, the orthographic projection of the first electrode 610 on the substrate 110 at least partially overlaps the orthographic projection of the pixel opening 330 on the substrate 110 so that each first electrode 610 can be exposed by a pixel opening 330.

In some embodiments, as shown in FIG. 1 to FIG. 4, the pixel openings 330 include a first pixel opening 330a and a second pixel opening 330b adjacent to each other in a first direction Y. At least one connecting via 131 is located between the first pixel opening 330a and the second pixel opening 330b. The minimum distance h1 from the orthographic projection of the connecting via 131 on the substrate 110 to the orthographic projection of the first pixel opening 330a on the substrate 110 is less than the minimum distance h2 from the orthographic projection of the connecting via 131 on the substrate 110 to the orthographic projection of the second pixel opening 330b on the substrate 110.

In these embodiments, the first pixel opening 330a and the second pixel opening 330b are adjacent to each other, and at least one connecting via 131 is located between the first pixel opening 330a and the second pixel opening 330b, that is, the orthographic projection of at least one connecting via 131 on the substrate 110 is located between the orthographic projection of the first pixel opening 330a on the substrate 110 and the orthographic projection of the second pixel opening 330b on the substrate 110, thereby alleviating the influence of the connecting via 131 on the light-emitting unit 310. In addition, the minimum distance h1 between the connecting via 131 and the first pixel opening 330a is shorter, that is, h1 is less than h2, and the connecting via 131 is disposed non-centrally with respect to the first pixel opening 330a and the second pixel opening 330b.

In one or more embodiments, for a connecting via 131 and a first pixel opening 330a and a second pixel opening 330b located on the two sides of the connecting via 131, the first electrode 610 corresponding to the first pixel opening 330a is electrically connected to the thin-film transistor 120 through the connecting via 131.

In these implementations, the minimum distance h1 between the connecting via 131 and the first pixel opening 330a is shorter, and the first electrode 610 corresponding to the first pixel opening 330a is electrically connected to the thin-film transistor 120 through the connecting via 131, thereby reducing the distance between the first electrode 610 and the thin-film transistor 120 and improving the stability of signal transmission.

In one or more embodiments, the first electrode 610 corresponding to the first pixel opening 330a is the first electrode 610 exposed by the first pixel opening 330a.

The touch lines 510a may be arranged in multiple manners. In some embodiments, the touch lines 510a include a first line 511. The first line 511 is located between the first pixel opening 330a and the second pixel opening 330b. The orthographic projection of the connecting via 131 on the substrate 110 at least partially overlaps the orthographic projection of the first line 511 on the substrate 110.

In these embodiments, the first line 511 is located between the first pixel opening 330a and the second pixel opening 330b. That is, the orthographic projection of the first line 511 on the substrate 110 is located between the orthographic projection of the first pixel opening 330a on the substrate 110 and the orthographic projection of the second pixel opening 330b on the substrate 110. The connecting via 131 is covered by the first line 511.

In one or more embodiments, the first pixel openings 330a and the second pixel openings 330b are spaced apart in the first direction Y. The width direction of the first line 511 is the first direction Y. The first line 511 is formed to extend in a second direction X. The second direction X is the length direction of the first line 511.

It can be seen from the above that the connecting via 131 located between the first pixel opening 330a and the second pixel opening 330b is disposed non-centrally. In this case, the first line 511 may be disposed non-centrally with respect to the edge of the first pixel opening 330a and the edge of the second pixel opening 330b adjacent to each other so that the first line 511 can cover the connecting via 131; or the width of the first line 511 may be widened so that the first line 511 can cover the non-centrally disposed connecting via 131.

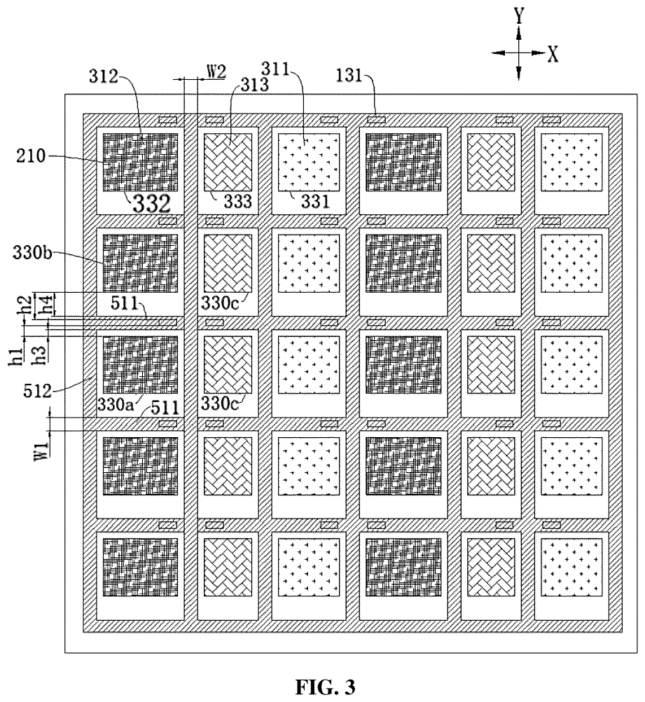

That is, as shown in FIG. 3, the minimum distance h3 from the orthographic projection of the first line 511 on the substrate 110 to the orthographic projection of the first pixel opening 330a on the substrate 110 is less than the minimum distance h4 from the orthographic projection of the first line 511 on the substrate 110 to the orthographic projection of the second pixel opening 330b on the substrate 110.

The distance h1 from the connecting via 131 to the first pixel opening 330a is shorter. In these embodiments, the distance h3 from the first line 511 to the first pixel opening 330a is shorter so that the first line 511 can better cover the connecting via 131 without changing the width of the first line 511.

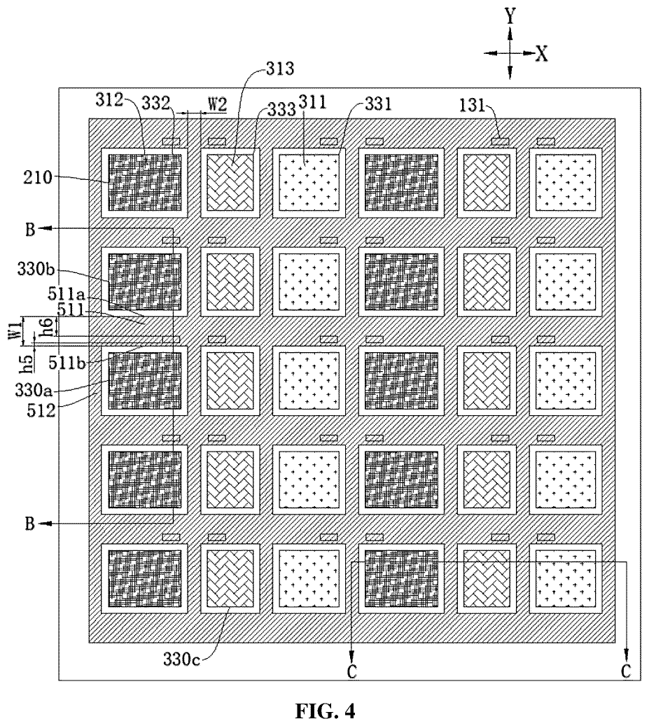

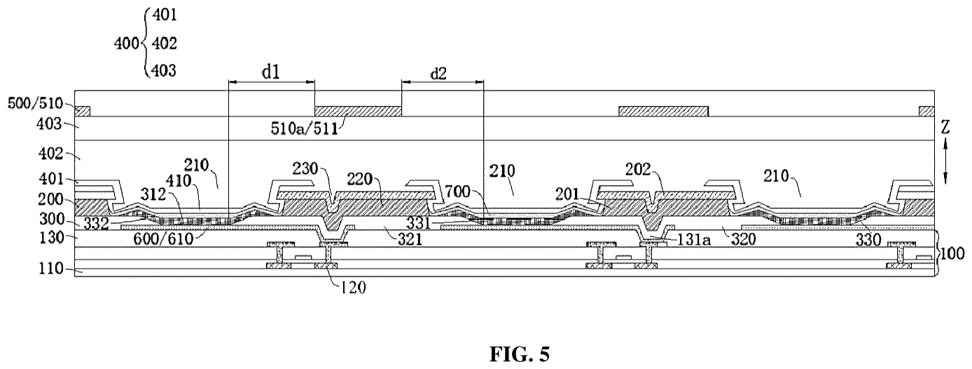

In some other embodiments, as shown in FIG. 4 and FIG. 5, the first line 511 may also be disposed centrally with respect to the edge of the first pixel opening 330a and the edge of the second pixel opening 330b adjacent to each other. Moreover, the orthographic projection of the first line 511 on the substrate 110 includes a first side edge 511a and a second side edge 511b opposite to each other in the first direction Y. The first side edge 511a is located on the side of the second side edge 511b facing the first pixel opening 330. The minimum distance h5 from the orthographic projection of the connecting via 131 on the substrate 110 to the first side edge 511a is less than the minimum distance h6 from the orthographic projection of the connecting via 131 on the substrate 110 to the second side edge 511b.

In these embodiments, the first line 511 is disposed centrally with respect to the edge of the first pixel opening 330a and the edge of the second pixel opening 330b adjacent to the edge of the first pixel opening 330a. As shown in FIG. 5, the distance between the first line 511 and the first pixel opening 330a is d1, and the distance between the first line 511 and the second pixel opening 330b is d2. d1 is equal to d2. Since the connecting via 131 is disposed non-centrally, the minimum distance h5 from the orthographic projection of the connecting via 131 on the substrate 110 to the first side edge 511a is less than the minimum distance h6 from the orthographic projection of the connecting via 131 on the substrate 110 to the second side edge 511b so that the first line 511 can better cover the connecting via 131.

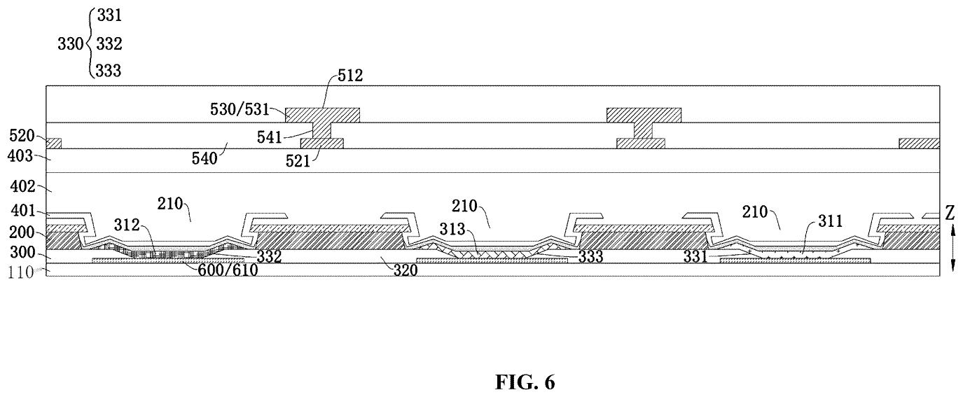

In one or more embodiments, as shown in FIG. 2 to FIG. 6, the touch lines 510a may also include a second line 512. The orthographic projection of the second line 512 on the substrate 110 and the orthographic projection of the connecting via 131 on the substrate 110 are staggered, that is, the second line 512 does not cover the connecting via 131. When the first line 511 is disposed non-centrally with respect to the edge of the first pixel opening 330a and the edge of the second pixel opening 330b adjacent to each other, that is, when the orthographic projection of the first line 511 on the substrate 110 is closer to the orthographic projection of the first pixel opening 330a on the substrate 110, the width of the first line 511 and the width of the second line 512 may be the same. When the first line 511 is disposed centrally with respect to the edge of the first pixel opening 330a and the edge of the second pixel opening 330b adjacent to each other, the width of the first line 511 may be greater than the width of the second line 512, that is, the touch line 510a is partially widened to cover the connecting via 131.

In some embodiments, the pixel openings 330 also include a third pixel opening 330c. The second line 512 is located between the first pixel opening 330a and the third pixel opening 330c. The minimum distance from the orthographic projection of the second line 512 on the substrate 110 to the orthographic projection of the first pixel opening 330a on the substrate 110 is equal to the minimum distance from the orthographic projection of the second line 512 on the substrate 110 to the orthographic projection of the third pixel opening 330c on the substrate 110.

In these embodiments, the second line 512 may be disposed centrally with respect to the first pixel opening 330a and the third pixel opening 330c so that the second line 512 has the relatively consistent light emission influence on the first pixel opening 330a and the third pixel opening 330c, improving the consistency of the display effect of the display panel.

Additionally/alternatively, the second line 512 is located between the second pixel opening 330b and the third pixel opening 330c such that the minimum distance from the orthographic projection of the second line 512 on the substrate 110 to the orthographic projection of the second pixel opening 330b on the substrate 110 is equal to the minimum distance from the orthographic projection of the second line 512 on the substrate 110 to the orthographic projection of the third pixel opening 330c on the substrate 110.

In these embodiments, the second line 512 may be disposed centrally with respect to the second pixel opening 330b and the third pixel opening 330c so that the second line 512 has the relatively consistent light emission influence on the second pixel opening 330b and the third pixel opening 330c, improving the consistency of the display effect of the display panel.

In one or more embodiments, as shown in FIG. 4, one connecting via 131 and another connecting via 131 may correspond to different first pixel openings 330a, different second pixel openings 330b, and different third pixel openings 330c. The first pixel opening 330a, the second pixel opening 330b, and the third pixel opening 330c are the first pixel opening 330a, the second pixel opening 330b, and the third pixel opening 330c with respect to one connecting via 131. For example, the first pixel opening 330a corresponding to one connecting via 131 may be the third pixel opening 330c corresponding to another connecting via 131. Illustratively, in two connecting vias 131 located in the first column and adjacent in the first direction Y, the first pixel opening 330a corresponding to one connecting via 131 may be the second pixel opening 330b corresponding to the next connecting via 131 in the same column or may be the third pixel opening 330c corresponding to a connecting via 131 in the next column.

In one or more embodiments, as shown in FIG. 4, the width W1 of the first line 511 may be greater than the width W2 of the second line 512 so that the width W1 of the first line 511 is larger to better cover the connecting via 131.

Alternatively, as shown in FIG. 3, in some other embodiments, the width W1 of the first line 511 may be equal to the width W2 of the second line 512, improving the uniformity of the display effect.

For example, the ratio of the width of the first line 511 to the width of the second line 512 is 1 to 2. For example, the ratio of the width of the first line 511 to the width of the second line 512 is 1, 1.2, 1.5, 1.8, or 2, alleviating the influence of a too-small width of the first line 511 on the covering effect of the first line 511 on the connecting via 131 due to a too small ratio of the width of the first line 511 to the width of the second line 512 and alleviating the influence of a too large width of the first line 511 on the light emission effect of the light-emitting unit 310.

The pixel openings 330 are arranged in multiple manners. For example, as shown in FIG. 1, FIG. 3, and FIG. 4, the pixel openings 330 are arranged in rows and columns in the first direction Y and the second direction X. The first direction Y is the column direction. The second direction X is the row direction. The first line 511 is located between two adjacent rows of pixel openings 330 in the first direction Y, and the first line 511 is formed to extend in the second direction X; and/or the second line 512 is located between two adjacent columns of pixel openings 330 in the second direction X, and the second line 512 is formed to extend in the first direction Y.

In these embodiments, the pixel openings 330 are arranged in rows and columns, the first line 511 is located between two adjacent rows of pixel openings 330 in the first direction Y, and the second line 512 is located between two adjacent columns of pixel openings 330, enabling a simple arrangement of the first line 511 and the second line 512 and facilitating the forming and manufacturing of the touch line 510a.

In one or more embodiments, the first line 511 may be disposed to correspond to a pixel opening 330, or the first line 511 extends in the second direction X and is arranged to correspond to two adjacent rows of pixel openings 330, better simplifying the shape of the first line 511.

In one or more embodiments, the second line 512 may be disposed to correspond to a pixel opening 330, or the second line 512 extends in the first direction Y and is arranged to correspond to two adjacent columns of pixel openings 330, better simplifying the shape of the second line 512.

In one or more embodiments, the touch lines 510a are all horizontal or vertical lines. The horizontal lines extending in the second direction X are all first lines 511, and the vertical lines extending in the first direction Y are all second lines 512, simplifying the arrangement of the touch lines 510a.

In some other embodiments, the first line 511 may also be part of a horizontal line extending in the second direction X. For example, the touch line 510a may be partially widened such that the first line 511 can cover the connecting via 131. The width of the part of the touch line 510a that extends in the second direction X and is staggered from the connecting via 131 may be equal to the width of the second line 512.

In one or more embodiments, the second line 512 is disposed centrally with respect to edges of the two columns of pixel openings 330 located on the two sides of the second line 512 so that the second line 512 has the same light emission influence on the light emitting units 310 located on the two sides of the second line 512, improving the display uniformity.

In one or more embodiments, the light-emitting units 310 include first light-emitting units 311, second light-emitting units 312, and third light-emitting units 313 having different emitted colors. The pixel openings 330 include first-type pixel openings 331, second-type pixel openings 332, and third-type pixel openings 333. The first-type pixel openings 331 are configured to accommodate the first light-emitting units 311. The second-type pixel openings 332 are configured to accommodate the second light-emitting units 312. The third-type pixel openings 333 are configured to accommodate the third light-emitting units 313.

The first light-emitting units 311, the second light-emitting units 312, and the third light-emitting units 313 are arranged in multiple manners. For example, as shown in FIG. 1, the first light-emitting units 311 and the second light-emitting units 312 are alternately arranged in the first direction Y to form first pixel columns, and the third light-emitting units 313 are sequentially arranged in the first direction Y to form second pixel columns. The first pixel columns and the second pixel columns are alternately arranged in the second direction X. In the second direction X, the first light-emitting units 311 and the third light-emitting units 313 are arranged side by side, or the second light-emitting units 312 and the third light-emitting units 313 are arranged side by side, reducing the spacing between the first light-emitting units 311, the second light-emitting units 312, and the third light-emitting units 313 and improving the display effect of the display panel.

In these embodiments, at least one first line 511 is located between a first light-emitting unit 311 and a second light-emitting unit 312 adjacent to each other in the first pixel column, and/or at least one first line 511 is located between two adjacent third light-emitting units 313 in the second pixel column. The first pixel opening 330a may be a first-type pixel opening 331, and the second pixel opening 330b may be a second-type pixel opening 332. Alternatively, both the third pixel opening 330c and the second pixel opening 330b are third-type pixel openings 333.

In one or more embodiments, at least one second line 512 is located between a first light-emitting unit 311 and a third light-emitting unit 313, and/or at least one second line 512 is located between a second light-emitting unit 312 and a third light-emitting unit 313.

In some other embodiments, as shown in FIG. 3 and FIG. 4, the first light-emitting units 311 are sequentially arranged in the first direction Y to form third pixel columns, the second light-emitting units 312 are sequentially arranged in the first direction Y to form fourth pixel columns, and the third light-emitting units 313 are sequentially arranged in the first direction Y to form fifth pixel columns. The third pixel columns, the fourth pixel columns, and the fifth pixel columns are alternately arranged in sequence. In these embodiments, the same type of light-emitting units 310 are arranged in columns, simplifying the pixel arrangement of the display panel.

In these embodiments, at least one first line 511 is located between two adjacent first light-emitting units 311 in the third pixel column, and/or at least one first line 511 is located between two adjacent second light-emitting units 312 in the fourth pixel column, and/or at least one first line 511 is located between two adjacent third light-emitting units 313 in the fifth pixel column. In these embodiments, the first pixel opening 330a and the second pixel opening 330b may both be first-type pixel openings 331, may both be second-type pixel openings 332, or may both be third-type pixel openings 333.

In one or more embodiments, the second line 512 is located between a third pixel column and a fourth pixel column adjacent to each other, and/or the second line 512 is located between a fourth pixel column and a fifth pixel column adjacent to each other, and/or the second line 512 is located between a third pixel column and a fifth pixel column adjacent to each other.

That is, when the light-emitting units 310 are arranged in rows and columns and the pixel openings 330 are arranged in rows and columns, the first line 511 may be located between two adjacent rows of light-emitting units 310, that is, the first line 511 may be located between two adjacent rows of pixel openings 330; and the second line 512 may be located between two adjacent columns of light-emitting units 310, that is, the second line 512 may be located between two adjacent columns of pixel openings 330.

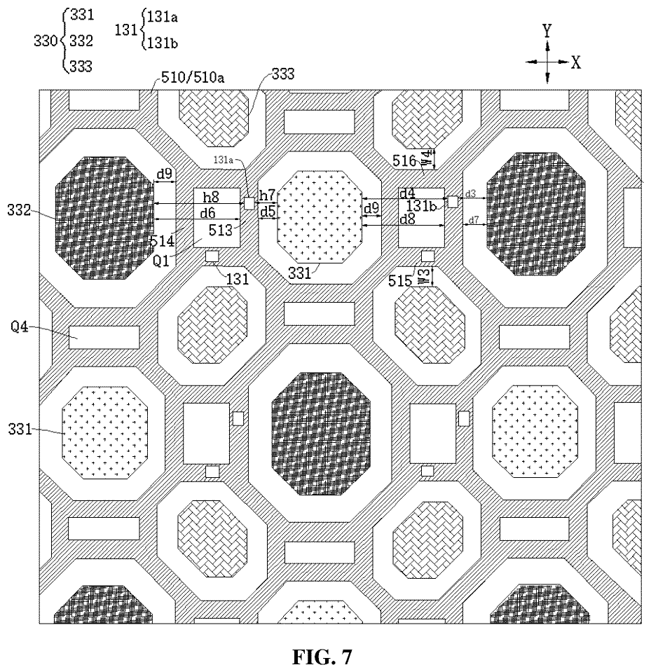

In some other embodiments, as shown in FIG. 7, the pixel openings 330 include first-type pixel openings 331 and second-type pixel openings 332. The first-type pixel openings 331 and the second-type pixel openings 332 are sequentially arranged in the second direction X to form first pixel opening rows. The first-type pixel opening 331 and the second-type pixel opening 332 adjacent to each other are spaced apart by a first gap Q1. At least one connecting via 131 is located in the first gap Q1. The touch lines 510a include a third line 513 and a fourth line 514 that are located in the first gap Q1 and spaced apart in the second direction X. The orthographic projection of the third line 513 on the substrate 110 at least partially overlaps the orthographic projection of the connecting via 131 on the substrate 110.

In these embodiments, the connecting via 131 is located in the first gap Q1 between the first-type pixel opening 331 and the second-type pixel opening 332 adjacent to each other, the touch lines 510a include the third line 513 and the fourth lines 514 arranged side by side in the first gap Q1, and the third line 513 is configured to cover the connecting via 131.

When the width of the first gap Q1 is large, if only one widened touch line 510a is disposed in the first gap Q1 to cover the connecting via 131, to make the distance between the touch line 510a and the first-type pixel opening 331 and the distance between the touch line 510a and the second-type pixel opening 332 small, the width of the touch line 510a is made too large, and the difference from the width of the touch line 510a in the region outside the first gap Q1 is made large, affecting the transmission of the touch signal; and if the width of the touch line 510a in the first gap Q1 is small, to make the touch line 510a cover the connecting via 131 corresponding to one of the first-type pixel opening 331 or the second-type pixel opening 332, the distance between the touch line 510a in the first gap Q1 and the first-type pixel opening 331 and the distance between the touch line 510a in the first gap Q1 and the second-type pixel opening 332 are made different from the distances between the touch line 510a at another position and the pixel openings 330, resulting in non-uniform display effect.

In this embodiment of this application, the third line 513 and the fourth line 514 are disposed in the first gap Q1 so that on the one hand, the width of the third line 513 and the width of the fourth line 514 can be kept as consistent as possible with widths of the touch lines 510a at other positions, and on the other hand, according to the arrangement requirement, the spacing between the orthographic projection of the third line 513 on the substrate 110 and the orthographic projection of the pixel opening 330 adjacent to the third line 513 on the substrate 110 can be close to the spacing between the orthographic projection of the fourth line 514 on the substrate 110 and the orthographic projection of the pixel opening 330 adjacent to the fourth line 514 on the substrate 110, improving the display uniformity.

In one or more embodiments, the connecting vias 131 include first vias 131a and second vias 131b. The first electrode 610 corresponding to the first-type pixel opening 331 is electrically connected to the corresponding thin-film transistor 120 through a first via 131a. The first electrode 610 corresponding to the second-type pixel opening 332 is electrically connected to the corresponding thin-film transistor 120 through a second via 131b.

In one or more embodiments, the distance between the first via 131a and the first-type pixel opening 331 may be made small, that is, for the first via 131a and the first-type pixel opening 331 and the second-type pixel opening 332 on the two sides of the first via 131a, the minimum distance h7 between the orthographic projection of the first via 131a on the substrate 110 and the orthographic projection of the first-type pixel opening 331 on the substrate 110 is smaller than the minimum distance h8 between the orthographic projection of the first via 131a on the substrate 110 and the orthographic projection of the second-type pixel opening 332 on the substrate 110, reducing the signal transmission distance.

In one or more embodiments, the distance between the second via 131b and the second-type pixel opening 332 may be made small, that is, for the second via 131b and the first-type pixel opening 331 and the second-type pixel opening 332 on the two sides of the second via 131b, the minimum distance d3 between the orthographic projection of the second via 131b on the substrate 110 and the orthographic projection of the second-type pixel opening 332 on the substrate 110 is less than the minimum distance d4 between the orthographic projection of the second via 131b on the substrate 110 and the orthographic projection of the first-type pixel opening 331 on the substrate 110, reducing the signal transmission distance.

When the third line 513 is used to cover the first via 131a, the distance between the third line 513 and the first-type pixel opening 331 may be made shorter. That is, the minimum distance between the orthographic projection of the third line 513 covering the first via 131a on the substrate 110 and the orthographic projection of the first-type pixel opening 331 on the substrate 110 is the first distance d5, the minimum distance between the orthographic projection of the third line 513 covering the first via 131a on the substrate 110 and the orthographic projection of the second-type pixel opening 332 on the substrate 110 is the second distance d6, and the first distance d5 is less than the second distance d6. Thus, the third line 513 can better cover the first via 131a.

When the third line 513 is used to cover the second via 131b, the distance between the third line 513 and the second-type pixel opening 332 may be made shorter. That is, the minimum distance between the orthographic projection of the third line 513 covering the second via 131b on the substrate 110 and the orthographic projection of the first-type pixel opening 331 on the substrate 110 is the third distance d8, the minimum distance between the orthographic projection of the third line 513 covering the second via 131b on the substrate 110 and the orthographic projection of the second-type pixel opening 332 on the substrate 110 is the fourth distance d7, and the third distance d8 is greater than the fourth distance d7. Thus, the third line 513 can better cover the second via 131b.

Referring to the preceding description, as shown in FIG. 7, the pixel openings 330 may also include third-type pixel openings 333. In some embodiments, the third-type pixel openings 333 are sequentially arranged in the second direction X to form second pixel opening rows, the first pixel opening rows and the second pixel opening rows are alternately arranged in the first direction Y, and a third-type pixel opening 333 is correspondingly disposed between the first-type pixel opening 331 and the second-type pixel opening 332 adjacent to each other.

In these embodiments, when the first-type pixel openings 331, the second-type pixel openings 332, and the third-type pixel openings 333 are arranged in the above manner, each third-type pixel opening 333 is located in a virtual quadrilateral S1, and the first-type pixel openings 331 and the second-type pixel openings 332 are alternately arranged at four corners of the virtual quadrilateral S1 so that the first-type pixel openings 331, the second-type pixel openings 332, and the third-type pixel openings 333 are arranged more uniformly, and same-color stripes are less likely to occur.

In one or more embodiments, the connecting vias 131 also include third vias 131c corresponding to the third-type pixel openings 333. The third via 131c is located in the first gap Q1. That is, in the first gap Q1, not only the first via 131a or the second via 131b is disposed, but also the connecting via 131 (that is, the third via 131c) corresponding to the third-type pixel opening 333 is disposed. In the same first gap Q1, connecting vias 131 corresponding to two pixel openings 330 are disposed.

In one or more embodiments, the touch lines 510a also include a fifth line 515 and a sixth line 516 located in the first gap Q1 and spaced apart in the first direction Y. The orthographic projection of the fifth line 515 on the substrate 110 at least partially overlaps the orthographic projection of the third via 131c on the substrate 110.

In these embodiments, the fifth line 515 is used to cover the third via 131c. The fifth line 515 and the sixth line 516 in the first gap Q1 are spaced apart in the first direction Y such that touch lines 510a at different positions have the same width and such that the distance from the fifth line 515 to the pixel opening 330 is close to the distance from the sixth line 516 to the pixel opening 330, making the touch lines 510a have the same light emission influence on the light-emitting units 310 and improving the display uniformity.

In one or more embodiments, at least one group of the third line 513, the sixth line 516, the fourth line 514, and the fifth line 515 located in the first gap Q1 are sequentially connected end to end so that touch signals can be transmitted between the third line 513, the sixth line 516, the fourth line 514, and the fifth line 515, improving the transmission effect of touch signals.

In one or more embodiments, a first spacing distance exists between the third line 513 and the pixel opening 330 on the side of the third line 513 facing away from the fourth line 514, and a second spacing distance d9 exists between the fourth line 514 and the pixel opening 330 on the side of the fourth line 514 facing away from the third line 513. For example, when the third line 513 is used to cover the first via 131a, the first distance d5 between the third line 513 and the first-type pixel opening 331 is the first spacing distance, and the second spacing distance d9 is the distance between the fourth line 514 and the second-type pixel opening 332. The absolute value of the difference between the first spacing distance and the second spacing distance d9 is less than or equal to 1.5 μm. That is, the absolute value of the difference between the first distance d5 and the second spacing distance d9 is less than or equal to 1.5 μm.

For example, when the third line 513 is used to cover the second via 131b, the fourth distance d7 between the third line 513 and the second-type pixel opening 332 is the first spacing distance, and the second spacing distance d9 is the distance between the fourth line 514 and the first-type pixel opening 331. The absolute value of the difference between the first spacing distance and the second spacing distance d9 is less than or equal to 1.5 μm. That is, the absolute value of the difference between the fourth distance d7 and the second spacing distance d9 is less than or equal to 1.5 μm.

The absolute value of the difference between the first spacing distance and the second spacing distance d9 is less than or equal to 1.5 μm. For example, the absolute value of the difference between the first spacing distance and the second spacing distance d9 is 0, 0.5 μm, 0.8 μm, 1.2 μm, or 1.5 μm.

In these embodiments, the difference between the first spacing distance and the second spacing distance d9 is relatively small so that the influence of the third line 513 on the light emission of the light-emitting unit 310 is close to the influence of the fourth line 514 on the light emission of the light-emitting unit 310, improving the display uniformity.

In one or more embodiments, a third spacing distance W3 exists between the fifth line 515 and the pixel opening 330 on the side of the fifth line 515 facing away from the sixth line 516, and a fourth spacing distance W4 exists between the sixth line 516 and the pixel opening 330 on the side of the sixth line 516 facing away from the fifth line 515. The absolute value of the difference between the third spacing distance W3 and the fourth spacing distance W4 is less than or equal to 1.5 μm. For example, the absolute value of the difference between the third spacing distance W3 and the fourth spacing distance W4 is 0, 0.5 μm, 0.8 μm, 1.2 μm, or 1.5 μm.

In these embodiments, the difference between the third spacing distance W3 and the fourth spacing distance W4 is relatively small so that the influence of the fifth line 515 on the light emission of the light-emitting unit 310 is close to the influence of the sixth line 516 on the light emission of the light-emitting unit 310, improving the display uniformity.

In one or more embodiments, the first gap Q1 is formed between the first-type pixel opening 331 and the second-type pixel opening 332 adjacent to each other in the second direction X. In some other embodiments, as shown in FIG. 7, a fourth gap Q4 is formed between the first light-emitting unit 311 and the second light-emitting unit 312 that are adjacent to each other in the first direction Y, multiple touch lines 510a may be disposed in the fourth gap Q4, and the touch lines 510a are connected end to end to improve width consistency of the touch lines 510a and consistency of the influences of the touch lines 510a on the light emission of the light-emitting unit 310.

In some embodiments, as shown in FIG. 1, the touch electrode layer 500 also includes notches 560. Two adjacent touch lines 510a are spaced apart by a notch 560. The orthographic projection of at least one notch 560 on the substrate 110 is located outside the orthographic projection of the connecting via 131 on the substrate 110.

In one or more embodiments, the touch electrode layer 500 may include multiple touch electrodes 510. The touch electrodes 510 are spaced apart and insulated from each other by the notches 560.

In these embodiments, the orthographic projection of at least one notch 560 on the substrate 110 is located outside the orthographic projection of the connecting via 131 on the substrate 110, that is, the notches 560 and the connecting vias 131 are staggered, so that more touch lines 510a can cover the connecting vias 131 to improve the display effect.

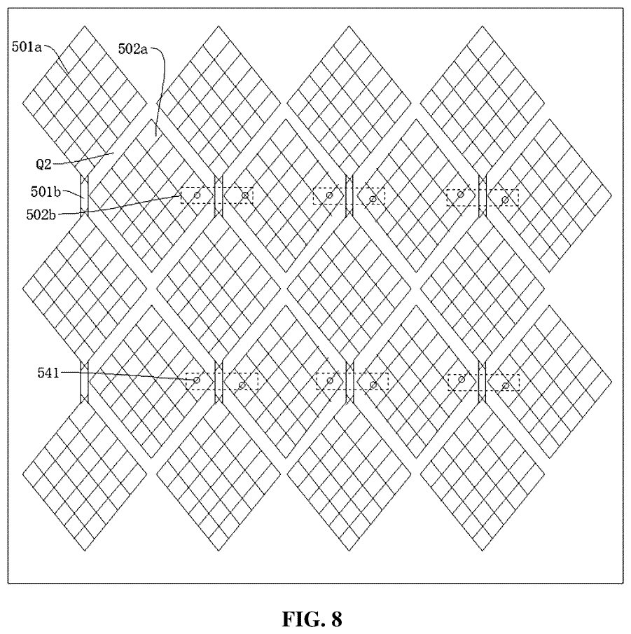

In some embodiments, as shown in FIG. 1 and FIG. 8, the touch electrodes 510 include first touch electrodes 501 extending in the first direction Y and arranged in the second direction X and second touch electrodes 502 extending in the second direction X and arranged in the first direction Y. A first touch electrode 501 includes a first touch portion 501a and a first connecting portion 501b. The first connecting portion 501b connects two adjacent first touch portions 501a. A second touch electrode 502 includes a second touch portion 502a and a second connecting portion 502b. The second connecting portion 502b connects two adjacent second touch portions 502a. A second gap Q2 is disposed between a first touch portion 501a and the second touch portion 502a adjacent to the first touch portion 501a. The orthographic projection of the second gap Q2 on the substrate 110 is located outside the orthographic projection of the connecting via 131 on the substrate 110.

In these embodiments, the second gap Q2 and the connecting via 131 are staggered so that more touch lines 510a can cover the connecting vias 131 to better improve the display effect.

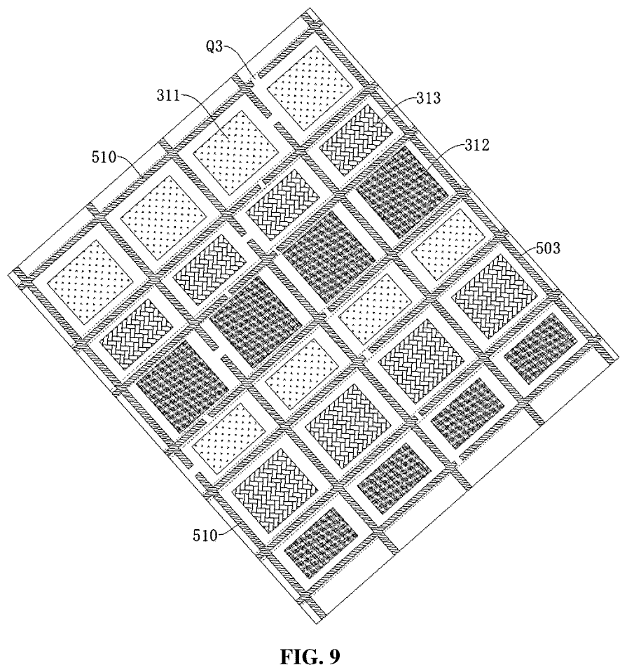

In some embodiments, as shown in FIG. 9, the touch electrode layer 500 also includes dummy electrodes 503. A third gap Q3 is disposed between a dummy electrode 503 and a touch electrode 510. The orthographic projection of the third gap Q3 on the substrate 110 is located outside the orthographic projection of the connecting via 131 on the substrate 110. The third gaps Q3 and the connecting vias 131 are staggered so that more touch lines 510a can cover the connecting vias 131 to better improve the display effect.

In some embodiments, as shown in FIG. 1 to FIG. 6, the display panel also includes the isolation structure 200 located on one side of the substrate 110. An isolation opening 210 is formed by being enclosed by the isolation structure 200. The orthographic projection of the first electrode 610 on the substrate 110 at least partially overlaps the orthographic projection of the isolation opening 210 on the substrate 110. The orthographic projection of the touch line 510a on the substrate 110 at least partially overlaps the orthographic projection of the isolation structure 200 on the substrate 110.

In these embodiments, the display panel also includes the isolation structure 200. The isolation opening 210 enclosed by the isolation structure 200 may be used for accommodating the light-emitting unit 310. The orthographic projection of the first electrode 610 on the substrate 110 at least partially overlaps the orthographic projection of the isolation opening 210 on the substrate 110 so that the first electrode 610 can be exposed by the isolation opening 210 to drive the light-emitting unit 310 to emit light. The orthographic projection of the touch line 510a on the substrate 110 at least partially overlaps the orthographic projection of the isolation structure 200 on the substrate 110 so that the touch line 510a can be located above the isolation structure 200, alleviating the influence of the touch line 510a on the light-emitting unit 310 in the isolation opening 210.

In one or more embodiments, the isolation structure 200 may be disposed on the side of the pixel defining portion 320 facing away from the substrate 110. Alternatively, the pixel defining portion 320 is provided with an avoidance opening, and the isolation structure 200 may be located in the avoidance opening. This embodiment of this application illustrates an example in which the isolation structure 200 is located on the side of the pixel defining portion 320 facing away from the substrate 110.

In one or more embodiments, the pixel openings 330 communicate with the isolation opening 210 so that light emitted by the light-emitting unit 310 in the pixel opening 330 can be emitted through the isolation opening 210. In one or more embodiments, the pixel opening 330 is located in the isolation opening 210, that is, the orthographic projection of the pixel opening 330 on the substrate 110 is located within the orthographic projection of the isolation opening 210 on the substrate 110, alleviating the influence of the isolation structure 200 on the light emission of the light-emitting unit 310.

The isolation structure 200 is arranged in multiple manners. In some embodiments, the isolation structure 200 includes a first sublayer 201 and a second sublayer 202 stacked in the direction away from the substrate 110. The orthographic projection of the first sublayer 201 on the substrate 110 is located within the orthographic projection of the second sublayer 202 on the substrate 110.

In these embodiments, the second sublayer 202 is located on the side of the first sublayer 201 facing away from the substrate 110 and the size of the second sublayer 202 is made greater than the size of the first sublayer 201 so that the second sublayer 202 can be recessed. When the light-emitting units 310 are manufactured, the light-emitting material may be broken at the edge of the second sublayer 202 to form mutually independent light-emitting units 310, without using a precise evaporation mask to manufacture the light-emitting units 310, thereby simplifying the preparation process of the display panel.

In one or more embodiments, the isolation structure 200 also includes a third sublayer (not shown) located on the side of the first sublayer 201 facing the substrate 110. The orthographic projection of the first sublayer 201 on the substrate 110 is located within the orthographic projection of the third sublayer on the substrate 110. With the third sublayer, in the manufacturing process of the isolation structure 200, when the first sublayer 201 is laterally etched such that the size of the first sublayer 201 is smaller than that of the second sublayer 202, the third sublayer can provide protection for the film layer of the isolation structure 200 facing the substrate 110.

In one or more embodiments, the material of the isolation structure 200 includes a conductive material, the second electrode layer includes multiple second electrodes 700, each second electrode 700 is located in a respective isolation opening 210, and the second electrodes 700 are electrically connected to the isolation structure 200 so that the second electrodes 700 can be interconnected through the isolation structure 200 to form a plane electrode. In one or more embodiments, the material of the first sublayer 201 may include a conductive material, and the second electrodes 700 and the first sublayer 201 are electrically connected. In one or more embodiments, the second electrodes 700 and the third sublayer are electrically connected, increasing the arrangement area of the conductive material and reducing the voltage drop of the second electrodes 700.

In one or more embodiments, the encapsulation layer 400 includes a first encapsulation layer 401. The first encapsulation layer 401 includes multiple encapsulation portions 410. The encapsulation portions 410 are configured to encapsulate the light-emitting units 310. An encapsulation portion 410 may extend from the isolation opening 210 to the isolation structure 200. Two adjacent encapsulation portions 410 may be spaced apart from each other, or two adjacent encapsulation portions 410 overlap each other on the isolation structure 200. The material of the first encapsulation layer 401 may include an inorganic material.

In one or more embodiments, the encapsulation layer 400 also includes a second encapsulation layer 402. The second encapsulation layer 402 is located on the side of the first encapsulation layer 401 facing away from the substrate 110. The second encapsulation layer 402 may be disposed on an entire surface. The material of the second encapsulation layer 402 may include an organic material.

In one or more embodiments, the encapsulation layer 400 also includes a third encapsulation layer 403. The third encapsulation layer 403 is located on the side of the second encapsulation layer 402 facing away from the substrate 110. The third encapsulation layer 403 may be disposed on an entire surface. The material of the third encapsulation layer 403 may include an inorganic material.

In one or more embodiments, the touch electrode layer 500 may be located on the side of the third encapsulation layer 403 facing away from the substrate 110 to alleviate the influence of the touch electrode layer 500 on the encapsulation effect.

In one or more embodiments, the orthographic projection of the connecting via 131 on the substrate 110 at least partially overlaps the orthographic projection of the isolation structure 200 on the substrate 110. That is, the isolation structure 200 covers at least part of the connecting via 131, alleviating the influence of the connecting via 131 on the light emission of the light-emitting unit 310.

In one or more embodiments, the orthographic projection of the connecting via 131 on the substrate 110 is located within the orthographic projection of the isolation structure 200 on the substrate 110 so that the isolation structure 200 can better cover the connecting via 131.

In some embodiments, the minimum distance between the edge of the orthographic projection of the isolation opening 210 on the substrate 110 and the edge of the orthographic projection of the touch line 510a on the substrate 110 is greater than 1 μm. For example, the minimum distance between the edge of the orthographic projection of the isolation opening 210 on the substrate 110 and the edge of the orthographic projection of the touch line 510a on the substrate 110 is 1.5 μm, 1.6 μm, 2 μm, 2.2 μm, or 3 μm, alleviating the influence of a too close distance between the touch line 510a and the isolation opening 210 on the light emission effect of the light-emitting unit 310.

In one or more embodiments, along the same direction, the width of the orthographic projection of the touch line 510a on the substrate 110 is less than the width of the orthographic projection of the isolation structure 200 on the substrate 110 and greater than the width of the orthographic projection of the connecting via 131 on the substrate 110. For example, when the touch line 510a includes a first line 511 located between two adjacent pixel openings 330 in the first direction Y, along the second direction X, the width of the first line 511 is less than the width of the isolation structure 200 for supporting the touch line 510a, and the width of the first line 511 is greater than the width of the connecting via 131 covered by the first line 511, ensuring that the touch line 510a can cover the connecting via 131 and does not extend into the isolation opening 210.

In one or more embodiments, the width of the touch line 510a is 3 μm to 6 μm, for example, 3 μm, 3.5 μm, 4 μm, 4.2 μm, 5 μm, 5.7 μm, or 6 μm, alleviating the difficulty in covering the connecting via 131 due to a too small width of the touch line 510a and alleviating the influence of a too large width of the touch line 510a on the light emission effect.

In one or more embodiments, the width of the connecting via 131 is 2 μm to 3.5 μm, for example, 2 μm, 2.2 μm, 2.7 μm, 3.0 μm, 3.3 μm, or 3.5 μm, alleviating the influence of a too-small width of the connecting via 131 on the electrical connection between the first electrode 610 and the thin-film transistor 120 and alleviating the influence of a too large width of the connecting via 131 on the display effect.

In one or more embodiments, the ratio of the width of the touch line 510a to the width of the connecting via 131 is 1 to 2, for example, 1, 1.1, 1.3, 1.5, 1.6, or 2, alleviating the difficulty in covering the connecting via 131 due to a too-small width of the touch line 510a and alleviating the influence of a too large width of the touch line 510a on the light emission effect.

In some embodiments, as shown in FIG. 1 and FIG. 5, the touch electrode layer 500 includes a first touch layer 520 and a second touch layer 530. An insulating dielectric layer 540 is disposed between the first touch layer 520 and the second touch layer 530. The touch electrode 510 includes a first touch segment 521 located in the first touch layer 520 and a second touch segment 531 located in the second touch layer 530. The insulating dielectric layer 540 is provided with dielectric vias 541. The first touch segment 521 is electrically connected to the second touch segment 531 through a dielectric via 541. The orthographic projections of the dielectric via 541 and at least one connecting via 131 on the substrate 110 are located on the same side of the orthographic projection of the same isolation opening 210 on the substrate 110.

In these embodiments, a gap is formed between adjacent isolation openings 210. The dielectric via 541 is generally disposed in a larger gap. It is possible to arrange the dielectric via 541 and the connecting via 131 in the same larger gap by arranging the dielectric via 541 and the connecting via 131 on the same side of the isolation opening 210, simplifying the arrangement of the connecting via 131 and the dielectric via 541.

As above, the light-emitting unit 310 may be located in the isolation opening 210. The second electrodes 700 are electrically connected to the isolation structure 200. When the isolation structure 200 includes the first sublayer 201, the second sublayer 202, and the third sublayer, the second electrodes 700 may be electrically connected to the first sublayer 201 and the third sublayer.

As shown in FIG. 1 to FIG. 9, an embodiment of a first aspect of this application provides a display panel. The display panel of this embodiment of this application and the display panel of any previous embodiment can be cross-referenced with each other. The display panel of this embodiment of this application includes a substrate 110, a first electrode layer 600, an isolation structure 200, and a touch electrode layer 500. The first electrode layer 600 is disposed on one side of the substrate 110 and includes a first electrode 610. The isolation structure 200 is located on the side of the substrate 110. The isolation opening 210 is formed by being enclosed by the isolation structure 200. The orthographic projection of the first electrode 610 on the substrate 110 at least partially overlaps the orthographic projection of the isolation opening 210 on the substrate 110. The isolation structure 200 includes a body portion 220 and a recessed portion 230 recessed from the body portion 220 toward the substrate 110. The touch electrode layer 500 is located on the side of the isolation structure 200 facing away from the substrate 110. The touch electrode layer 500 includes touch lines 510a. The orthographic projection of the recessed portion 230 on the substrate 110 at least partially overlaps the orthographic projection of a touch line 510a on the substrate 110.

In the display panel of this embodiment of this application, the display panel includes the substrate 110, the first electrode layer 600, the isolation structure 200, and the touch electrode layer 500. The isolation opening 210 is formed by being enclosed by the isolation structure 200. The isolation opening 210 can be configured to accommodate the light-emitting unit 310. The orthographic projection of the first electrode 610 on the substrate 110 at least partially overlaps the orthographic projection of the isolation opening 210 on the substrate 110 so that at least part of the first electrode 610 can be exposed by the isolation opening 210. The first electrode 610 can be configured to drive the light-emitting unit 310 in the isolation opening 210 to emit light. The isolation structure 200 includes the body portion 220 and the recessed portion 230. The surface of the recessed portion 230 is recessed toward the substrate 110. The reflected light on the surface of the recessed portion 230 affects the display effect of the display panel. The touch electrode layer 500 is located on the isolation structure 200. The touch electrode 510 is configured to implement a touch function of the display panel. The orthographic projection of the recessed portion 230 on the substrate 110 at least partially overlaps the orthographic projection of the touch line 510a on the substrate 110 so that the touch line 510a can cover at least part of the recessed portion 230, improving the display effect of the display panel.

The recessed portion 230 occurs for various reasons. When the film material is unevenly arranged during the manufacturing of the isolation structure 200, the recessed portion 230 may be formed on the isolation structure 200.

In some other embodiments, referring to the preceding description, the display panel also includes a thin-film transistor 120 and a first insulating layer 130. The first insulating layer 130 is provided with a connecting via 131 penetrating the first insulating layer 130. The first electrode layer 600 is located on the side of the first insulating layer 130 facing away from the thin-film transistor 120. The first electrode 610 is electrically connected to the thin-film transistor 120 through the connecting via 131. In one or more embodiments, the orthographic projection of the recessed portion 230 on the substrate 110 at least partially overlaps the orthographic projection of the isolation structure 200 on the substrate 110.

In these embodiments, due to the connecting via 131, when the isolation structure 200 is manufactured, part of the material falls into the connecting via 131 to cause the recessed portion 230 to be formed on the isolation structure 200; therefore, the orthographic projection of the recessed portion 230 on the substrate 110 at least partially overlaps the orthographic projection of the isolation structure 200 on the substrate 110.

In one or more embodiments, the orthographic projection of the touch line 510a on the substrate 110 is located within the orthographic projection of the isolation structure 200 on the substrate 110, alleviating the influence of the touch line 510a on the light emission effect of the light-emitting unit 310.

In some embodiments, the orthographic projection of the recessed portion 230 on the substrate 110 is located within the orthographic projection of the touch line 510a on the substrate 110, and the orthographic projection of the connecting via 131 on the substrate 110 is located within the orthographic projection of the touch line 510a on the substrate 110.

In these embodiments, the orthographic projection of the recessed portion 230 on the substrate 110 is located within the orthographic projection of the touch line 510a on the substrate 110 so that the touch line 510a can better cover the recessed portion 230, better improving the display effect. Moreover, the orthographic projection of the connecting via 131 on the substrate 110 is located within the orthographic projection of the touch line 510a on the substrate 110 so that the touch line 510a can better cover the connecting via 131 to better improve the display effect.

In one or more embodiments, referring to the preceding description, the display panel may also include a pixel definition layer 300. The pixel definition layer 300 includes a pixel defining portion 320 and pixel openings 330. For the arrangement of the pixel defining portion 320 and the pixel opening 330, reference can be made to the preceding description. The details are not described here again.

In one or more embodiments, multiple pixel openings 330 include the first pixel openings 330a and the second pixel openings 330b described earlier. For the relative position relationship between the connecting via 131 and each of the first pixel opening 330a and the second pixel opening 330b, reference can be made to the preceding description. The details are not described here again.

In one or more embodiments, the touch lines 510a may include the first line 511 described earlier. The touch lines 510a may also include the second line 512 described earlier. For the arrangement of the first line 511 and the second line 512, reference can be made to the preceding description. The details are not described here again.

As shown in FIG. 1 to FIG. 9, an embodiment of the first aspect of this application further provides a display panel. The display panel of this embodiment of this application and the display panel of any previous embodiment can be cross-referenced with each other. The display panel of this embodiment of this application includes a substrate 110, a first electrode layer 600, an isolation structure 200, and a light-shielding layer 270. The first electrode layer 600 is disposed on the side of the substrate 110 and includes a first electrode 610. An isolation opening 210 is formed by being enclosed by the isolation structure 200. The orthographic projection of the first electrode 610 on the substrate 110 at least partially overlaps the orthographic projection of the isolation opening 210 on the substrate 110. The isolation structure 200 includes a body portion 220 and a recessed portion 230 recessed from the body portion 220 toward the substrate 110. The light shielding layer is located on the side of the isolation structure 200 facing away from the substrate 110. The light shielding layer includes a light-shielding portion. The orthographic projection of the recessed portion 230 on the substrate 110 at least partially overlaps the orthographic projection of the light-shielding portion on the substrate 110.

In the display panel of this embodiment of this application, the display panel includes a substrate 110, a first electrode layer 600, an isolation structure 200, and a touch electrode layer 500. An isolation opening 210 is formed by being enclosed by the isolation structure 200. The isolation opening 210 may be configured to accommodate the light-emitting unit 310. The orthographic projection of the first electrode 610 on the substrate 110 at least partially overlaps the orthographic projection of the isolation opening 210 on the substrate 110 so that at least part of the first electrode 610 can be exposed by the isolation opening 210. The first electrode 610 can be configured to drive the light-emitting unit 310 in the isolation opening 210 to emit light. The isolation structure 200 includes a body portion 220 and a recessed portion 230. The surface of the recessed portion 230 is recessed toward the substrate 110. The reflected light on the surface of the recessed portion 230 affects the display effect of the display panel. The light-shielding layer 270 is located on the isolation structure 200. The orthographic projection of the recessed portion 230 on the substrate 110 at least partially overlaps the orthographic projection of the light-shielding portion of the light-shielding layer 270 on the substrate 110 so that the light-shielding portion can cover at least part of the recessed portion 230, improving the display effect of the display panel.

In one or more embodiments, the orthographic projection of the recessed portion 230 on the substrate 110 is located within the orthographic projection of the light-shielding portion on the substrate 110 so that the light-shielding portion can better cover the recessed portion 230.

The light-shielding portion is arranged in various manners. For example, the light-shielding portion includes the touch line 510a. Alternatively, in a display product with a filter, the light-shielding portion may include a black matrix located on the side of the touch electrode layer 500 facing away from the substrate 110. The light-shielding portion is formed of a light-shielding material. For the shape and arrangement of the light-shielding portion, reference can be made to the shape and arrangement of the touch line 510a. In one or more embodiments, the light-shielding portion has a mesh structure. The opening portions of the mesh structure are disposed corresponding to the pixel openings 330 so that the arrangement area of the light-shielding portion can be increased without affecting the light emission of the light-emitting units 310 and so that the light-shielding portion can cover more recessed portions 230.

In one or more embodiments, the preceding display panel also includes the thin-film transistor 120 and the first insulating layer 130 described earlier. The first insulating layer 130 includes a connecting via 131. The first electrode 610 is electrically connected to the thin-film transistor 120 through the connecting via 131. The orthographic projection of the connecting via 131 on the substrate 110 at least partially overlaps the orthographic projection of the recessed portion 230 on the substrate 110. The orthographic projection of the connecting via 131 on the substrate 110 is located within the orthographic projection of the light-shielding portion on the substrate 110.

In these embodiments, the orthographic projection of the connecting via 131 on the substrate 110 is located within the orthographic projection of the light-shielding portion on the substrate 110 so that the touch line 510a can better cover the connecting via 131 to better improve the display effect.

The composition, manufacturing, and other details of the isolation structure 200 in any preceding embodiment are further described in patents PCT/CN 2023/134518, 202310759370.2, 202310740412.8, 202310707209.0, 202311346196.5, and 202310909421.5 for reference.

An embodiment of a second aspect of this application also provides a display device. The display device includes the display panel of any embodiment in the first aspect. The display device provided by the embodiment of the second aspect of this application includes the display panel in any embodiment of the first aspect and thus has the same beneficial effects as the display panel of any embodiment in the first aspect. The details are not described here again.

The display device of this embodiment of this application includes, but is not limited to, a device having a display function, for example, a mobile phone, a personal digital assistant (PDA), a tablet computer, an e-book, a television, an access control, an intelligent fixed-line telephone, or a console.

The preceding embodiments of this application do not describe all details and do not limit this application. Apparently, many modifications and variations are possible in light of the preceding description. These embodiments are chosen and described in detail in the specification to better explain the principle and practical application of this application, thereby enabling those skilled in the art to make better use of this application and modifications thereof. This application is limited by only the claims, full scope, and equivalents of this application.

What is claimed is:

1. A display panel, comprising:
a substrate provided with a thin-film transistor on one side of the substrate;
a first insulating layer disposed on a side of the thin-film transistor facing away from the substrate and provided with a connecting via penetrating the first insulating layer;
a first electrode layer comprising a first electrode electrically connected to the thin-film transistor through the connecting via; and
a touch electrode layer comprising a touch electrode, wherein the touch electrode is located on a side of the first electrode layer facing away from the substrate, the touch electrode comprises a touch line, and an orthographic projection of the touch line on the substrate at least partially overlaps an orthographic projection of the connecting via on the substrate.

2. The display panel of claim 1, wherein the orthographic projection of the connecting via on the substrate is located within the orthographic projection of the touch line on the substrate.

3. The display panel of claim 1, further comprising a pixel definition layer located on the side of the first electrode layer facing away from the substrate, wherein the pixel definition layer comprises a pixel defining portion and a plurality of pixel openings, and an orthographic projection of the first electrode on the substrate at least partially overlaps an orthographic projection of a pixel opening of the plurality of pixel openings on the substrate; and
the plurality of pixel openings comprise a first pixel opening and a second pixel opening adjacent to each other in a first direction, at least one connecting via is located between the first pixel opening and the second pixel opening, and a minimum distance from an orthographic projection of the at least one connecting via on the substrate to an orthographic projection of the first pixel opening on the substrate is less than a minimum distance from the orthographic projection of the at least one connecting via on the substrate to an orthographic projection of the second pixel opening on the substrate.

4. The display panel of claim 3, wherein
the touch line comprises a first line, the first line is located between the first pixel opening and the second pixel opening, and the orthographic projection of the at least one connecting via on the substrate at least partially overlaps an orthographic projection of the first line on the substrate; and
a minimum distance from the orthographic projection of the first line on the substrate to the orthographic projection of the first pixel opening on the substrate is less than a minimum distance from the orthographic projection of the first line on the substrate to the orthographic projection of the second pixel opening on the substrate; or
the first line is disposed centrally with respect to an edge of the first pixel opening and an edge of the second pixel opening adjacent to the edge of the first pixel opening, the orthographic projection of the first line on the substrate comprises a first side edge and a second side edge opposite to each other in the first direction, the first side edge is located on a side of the second side edge facing the first pixel opening, and a minimum distance from the orthographic projection of the at least one connecting via on the substrate to the first side edge is less than a minimum distance from the orthographic projection of the at least one connecting via on the substrate to the second side edge.

5. The display panel of claim 4, wherein the touch line further comprises a second line connected to the first line, and an orthographic projection of the second line on the substrate and the orthographic projection of the at least one connecting via on the substrate are staggered;
the plurality of pixel openings further comprise a third pixel opening, and
the second line is located between the first pixel opening and the third pixel opening, and a minimum distance from the orthographic projection of the second line on the substrate to the orthographic projection of the first pixel opening on the substrate is equal to a minimum distance from the orthographic projection of the second line on the substrate to an orthographic projection of the third pixel opening on the substrate; or
the second line is located between the second pixel opening and the third pixel opening, and a minimum distance from the orthographic projection of the second line on the substrate to the orthographic projection of the second pixel opening on the substrate is equal to a minimum distance from the orthographic projection of the second line on the substrate to an orthographic projection of the third pixel opening on the substrate.

6. The display panel of claim 5, wherein a width of the first line is greater than a width of the second line, or a width of the first line is equal to a width of the second line;
a ratio of the width of the first line to the width of the second line is 1 to 2; and
the second line is disposed centrally with respect to edges of two columns of pixel openings located on two sides of the second line.

7. The display panel of claim 5, wherein the plurality of pixel openings are arranged in rows and columns along the first direction and a second direction, the first direction is a column direction, and the second direction is a row direction;
the first line is located between two adjacent rows of pixel openings in the first direction, and the first line extends in the second direction; and
the second line is located between two adjacent columns of pixel openings in the second direction, and the second line is formed to extend in the first direction.

8. The display panel of claim 7, further comprising a plurality of light-emitting units, wherein the plurality of light-emitting units comprise a plurality of first light-emitting units, a plurality of second light-emitting units, and a plurality of third light-emitting units having different emitted colors, the plurality of first light-emitting units and the plurality of second light-emitting units are alternately arranged in the first direction to form first pixel columns, the plurality of third light-emitting units are sequentially arranged in the first direction to form second pixel columns, and the first pixel columns and the second pixel columns are alternately arranged in the second direction; and
at least one first line is located between a first light-emitting unit and a second light-emitting unit adjacent to each other in a first pixel column of the first pixel columns, or at least one first line is located between two adjacent third light-emitting units in a second pixel column of the second pixel columns.

9. The display panel of claim 7, further comprising a plurality of light-emitting units, wherein the plurality of light-emitting units comprise a plurality of first light-emitting units, a plurality of second light-emitting units, and a plurality of third light-emitting units having different emitted colors, the plurality of first light-emitting units are sequentially arranged in the first direction to form third pixel columns, the plurality of second light-emitting units are sequentially arranged in the first direction to form fourth pixel columns, the plurality of third light-emitting units are sequentially arranged in the first direction to form fifth pixel columns, and the third pixel columns, the fourth pixel columns, and the fifth pixel columns are sequentially alternately arranged; and
at least one first line is located between two adjacent first light-emitting units in the third pixel columns, or at least one first line is located between two adjacent second light-emitting units in the fourth pixel columns, or at least one first line is located between two adjacent third light-emitting units in the fifth pixel columns.

10. The display panel of claim 3, wherein the plurality of pixel openings comprise a plurality of first-type pixel openings and a plurality of second-type pixel openings, and the plurality of first-type pixel openings and the plurality of second-type pixel openings are sequentially arranged in a second direction to form a plurality of first pixel opening rows;
among the plurality of first-type pixel openings and the plurality of second-type pixel openings, a first-type pixel opening and a second-type pixel opening that are adjacent to each other are spaced apart by a first gap, and at least one connecting via is located in the first gap; and
the touch line comprises a third line and a fourth line that are located in the first gap and spaced apart from each other in the second direction, and an orthographic projection of the third line on the substrate at least partially overlaps an orthographic projection of the at least one connecting via on the substrate.

11. The display panel of claim 10, wherein a plurality of connecting vias comprise a plurality of first vias and a plurality of second vias, and among the plurality of first-type pixel openings and the plurality of second-type pixel openings and among the plurality of first vias and the plurality of second vias,
a first electrode corresponding to a first-type pixel opening is electrically connected to a corresponding thin-film transistor through a corresponding first via, and a first electrode corresponding to a second-type pixel opening is electrically connected to a corresponding thin-film transistor through a corresponding second via;
for a first via, a first-type pixel opening on one side of the first via, and a second-type pixel opening on the other side of the first via, a minimum distance between an orthographic projection of the first via on the substrate and an orthographic projection of the first-type pixel opening on the substrate is less than a minimum distance between the orthographic projection of the first via on the substrate and an orthographic projection of the second-type pixel opening on the substrate, a minimum distance between an orthographic projection of a third line covering the first via on the substrate and the orthographic projection of the first-type pixel opening on the substrate is a first distance, a minimum distance between the orthographic projection of the third line covering the first via on the substrate and the orthographic projection of the second-type pixel opening on the substrate is a second distance, and the first distance is less than the second distance; and
for a second via, a first-type pixel opening on one side of the second via, and a second-type pixel opening on the other side of the second via, a minimum distance between an orthographic projection of the second via on the substrate and an orthographic projection of the second-type pixel opening on the substrate is less than a minimum distance between the orthographic projection of the second via on the substrate and an orthographic projection of the first-type pixel opening on the substrate, a minimum distance between an orthographic projection of a third line covering the second via on the substrate and the orthographic projection of the first-type pixel opening on the substrate is a third distance, a minimum distance between the orthographic projection of the third line covering the second via on the substrate and the orthographic projection of the second-type pixel opening on the substrate is a fourth distance, and the third distance is greater than the fourth distance.

12. The display panel of claim 10, wherein the plurality of pixel openings further comprise a plurality of third-type pixel openings, the plurality of third-type pixel openings are sequentially arranged in the second direction to form a plurality of second pixel opening rows, the plurality of first pixel opening rows and the plurality of second pixel opening rows are alternately arranged in the first direction, and a third-type pixel opening of the plurality of third-type pixel openings is correspondingly disposed between a first-type pixel opening and a second-type pixel opening adjacent to each other among the plurality of first-type pixel openings and the plurality of second-type pixel openings;
the connecting via further comprises a plurality of third vias corresponding to the plurality of third-type pixel openings, and a third via of the plurality of third vias is located in the first gap;
the touch line further comprises a fifth line and a sixth line located in the first gap and spaced apart from each other in the first direction, and an orthographic projection of the fifth line on the substrate at least partially overlaps an orthographic projection of the third via on the substrate; and
at least one group of the third line, the sixth line, the fourth line, and the fifth line located in the first gap are sequentially connected end to end.

13. The display panel of claim 12, wherein
a first spacing distance exists between the third line and a pixel opening on a side of the third line facing away from the fourth line, a second spacing distance exists between the fourth line and a pixel opening on a side of the fourth line facing away from the third line, and an absolute value of a difference between the first spacing distance and the second spacing distance is less than or equal to 1.5 μm; and
a third spacing distance exists between the fifth line and a pixel opening on a side of the fifth line facing away from the sixth line, a fourth spacing distance exists between the sixth line and a pixel opening on a side of the sixth line facing away from the fifth line, and an absolute value of a difference between the third spacing distance and the fourth spacing distance is less than or equal to 1.5 μm.

14. The display panel of claim 1, wherein the touch electrode layer further comprises a notch, two adjacent touch lines are spaced apart by the notch, and an orthographic projection of at least one notch on the substrate is located outside the orthographic projection of the connecting via on the substrate.

15. The display panel of claim 1, wherein the touch electrode comprises a plurality of first touch electrodes extending in a first direction and arranged in a second direction and a plurality of second touch electrodes extending in the second direction and arranged in the first direction, and among the plurality of first touch electrodes and the plurality of second touch electrodes,
a first touch electrode comprises a first touch portion and a first connecting portion, and the first connecting portion connects two adjacent first touch portions;
a second touch electrode comprises a second touch portion and a second connecting portion, and the second connecting portion connects two adjacent second touch portions; and
a second gap exists between the first touch portion and the second touch portion adjacent to the first touch portion, and an orthographic projection of the second gap on the substrate is located outside the orthographic projection of the connecting via on the substrate.

16. The display panel of claim 1, further comprising an isolation structure located on one side of the substrate, wherein an isolation opening is formed by being enclosed by the isolation structure, an orthographic projection of the first electrode on the substrate at least partially overlaps an orthographic projection of the isolation opening on the substrate, and the orthographic projection of the touch line on the substrate at least partially overlaps an orthographic projection of the isolation structure on the substrate; and
the orthographic projection of the connecting via on the substrate is located within the orthographic projection of the isolation structure on the substrate.

17. The display panel of claim 16, wherein a minimum distance between an edge of the orthographic projection of the isolation opening on the substrate and an edge of the orthographic projection of the touch line on the substrate is greater than 1 μm.

18. The display panel of claim 16, wherein in a same direction, a width of the orthographic projection of the touch line on the substrate is less than a width of the orthographic projection of the isolation structure on the substrate and greater than a width of the orthographic projection of the connecting via on the substrate;
a width of the touch line is 3 μm to 6 μm;
a width of the connecting via is 2 μm to 3.5 μm; and
a ratio of the width of the touch line to the width of the connecting via is 1 to 2.

19. The display panel of claim 16, wherein the touch electrode layer comprises a first touch layer and a second touch layer, an insulating dielectric layer is disposed between the first touch layer and the second touch layer, the touch electrode comprises a first touch segment located in the first touch layer and a second touch segment located in the second touch layer, the insulating dielectric layer is provided with a dielectric via, the first touch segment is electrically connected to the second touch segment through the dielectric via, and an orthographic projection of the dielectric via on the substrate and an orthographic projection of at least one connecting via on the substrate are located on a same side of an orthographic projection of a same isolation opening on the substrate.

20. The display panel of claim 16, further comprising:
a light-emitting unit, at least part of the light-emitting unit being located in the isolation opening; and
a second electrode located on a side of the light-emitting unit facing away from the substrate and electrically connected to the isolation structure;
wherein the isolation structure comprises a first sublayer and a second sublayer stacked in a direction away from the substrate, and an orthographic projection of the first sublayer on the substrate is located within an orthographic projection of the second sublayer on the substrate.

21. A display panel, comprising:
a substrate;
a first electrode layer disposed on a side of the substrate and comprising a first electrode;
an isolation structure located on the side of the substrate, wherein an isolation opening is formed by being enclosed by the isolation structure, an orthographic projection of the first electrode on the substrate at least partially overlaps an orthographic projection of the isolation opening on the substrate, and the isolation structure comprises a body portion and a recessed portion recessed from the body portion toward the substrate; and
a touch electrode layer located on a side of the isolation structure facing away from the substrate, wherein the touch electrode layer comprises a touch line, and an orthographic projection of the recessed portion on the substrate at least partially overlaps an orthographic projection of the touch line on the substrate.

22. The display panel of claim 21, wherein a thin-film transistor and a first insulating layer are sequentially disposed on the side of the substrate, the first insulating layer is provided with a connecting via penetrating the first insulating layer, the first electrode layer is located on a side of the first insulating layer facing away from the thin-film transistor, and the first electrode is electrically connected to the thin-film transistor through the connecting via; and
the orthographic projection of the recessed portion on the substrate at least partially overlaps an orthographic projection of the connecting via on the substrate.

23. The display panel of claim 22, wherein the orthographic projection of the recessed portion on the substrate is located within the orthographic projection of the touch line on the substrate, and the orthographic projection of the connecting via on the substrate is located within the orthographic projection of the touch line on the substrate.

24. The display panel of claim 22, further comprising a pixel definition layer located on a side of the first electrode layer facing away from the substrate, wherein the pixel definition layer comprises a pixel defining portion and a plurality of pixel openings, and the orthographic projection of the first electrode on the substrate at least partially overlaps an orthographic projection of a pixel opening among the plurality of pixel openings on the substrate; and
the plurality of pixel openings comprise a first pixel opening and a second pixel opening adjacent to each other in a first direction, at least one connecting via is located between the first pixel opening and the second pixel opening, and a minimum distance from an orthographic projection of the at least one connecting via on the substrate to an orthographic projection of the first pixel opening on the substrate is less than a minimum distance from the at least one orthographic projection of the connecting via on the substrate to an orthographic projection of the second pixel opening on the substrate.

25. The display panel of claim 24, wherein
the touch line comprises a first line, the first line is located between the first pixel opening and the second pixel opening, and the orthographic projection of the at least one connecting via on the substrate at least partially overlaps an orthographic projection of the first line on the substrate; and
a minimum distance from the orthographic projection of the first line on the substrate to the orthographic projection of the first pixel opening on the substrate is less than a minimum distance from the orthographic projection of the first line on the substrate to the orthographic projection of the second pixel opening on the substrate; or
the first line is disposed centrally with respect to an edge of the first pixel opening and an edge of the second pixel opening adjacent to the edge of the first pixel opening, the orthographic projection of the first line on the substrate comprises a first side edge and a second side edge opposite to each other in the first direction, the first side edge is located on a side of the second side edge facing the first pixel opening, and a minimum distance from the orthographic projection of the connecting via on the substrate to the first side edge is less than a minimum distance from the orthographic projection of the connecting via on the substrate to the second side edge.

26. The display panel of claim 25, wherein the touch line further comprises a second line connected to the first line, and an orthographic projection of the second line on the substrate and the orthographic projection of the at least one connecting via on the substrate are staggered; and
the pixel opening further comprises a third pixel opening, the second line is located between the first pixel opening and the third pixel opening, and a minimum distance from the orthographic projection of the second line on the substrate to the orthographic projection of the first pixel opening on the substrate is equal to a minimum distance from the orthographic projection of the second line on the substrate to an orthographic projection of the third pixel opening on the substrate; or
the second line is located between the second pixel opening and the third pixel opening, and a minimum distance from the orthographic projection of the second line on the substrate to the orthographic projection of the second pixel opening on the substrate is equal to a minimum distance from the orthographic projection of the second line on the substrate to an orthographic projection of the third pixel opening on the substrate.

27. A display panel, comprising:
a substrate;
a first electrode layer disposed on a side of the substrate and comprising a first electrode;
an isolation structure located on the side of the substrate, wherein an isolation opening is formed by being enclosed by the isolation structure, an orthographic projection of the first electrode on the substrate at least partially overlaps an orthographic projection of the isolation opening on the substrate, and the isolation structure comprises a body portion and a recessed portion recessed from the body portion toward the substrate; and
a light-shielding layer located on a side of the isolation structure facing away from the substrate, wherein the light-shielding layer comprises a light-shielding portion, and an orthographic projection of the recessed portion on the substrate at least partially overlaps an orthographic projection of the light-shielding portion on the substrate.

28. The display panel of claim 27, wherein the orthographic projection of the recessed portion on the substrate is located within the orthographic projection of the light-shielding portion on the substrate; and
the light-shielding portion comprises a touch line or a black matrix.

29. The display panel of claim 28, wherein a thin-film transistor and a first insulating layer are sequentially disposed on the side of the substrate, the first insulating layer is provided with a connecting via penetrating the first insulating layer, the first electrode layer is located on a side of the first insulating layer facing away from the thin-film transistor, and the first electrode is electrically connected to the thin-film transistor through the connecting via; and
an orthographic projection of the connecting via on the substrate at least partially overlaps the orthographic projection of the recessed portion on the substrate, and the orthographic projection of the connecting via on the substrate is located within the orthographic projection of the light-shielding portion on the substrate.

30. A display device, comprising the device panel of claim 1.
